(19) United States
(12) Patent Application Publication
(10) Pub. No.: US 2025/0233037 A1
(43) Pub. Date: Jul. 17, 2025

(54) CAVITY INTEGRATED CIRCUIT

(71) Applicant: TEXAS INSTRUMENTS INCORPORATED, DALLAS, TX (US)

(72) Inventors: Masamitsu Matsuura, BEPPU-SHI OITA-KEN (JP); Daiki Komatsu, BEPPU-SHI OITA-KEN (JP); Mao Sugeno, BEPPU-SHI OITA-KEN (JP)

(21) Appl. No.: 18/413,360

(22) Filed: Jan. 16, 2024

(51) Int. Cl. H01L 23/31; H01L 21/762; H01L 21/768; H01L 23/498

(52) U.S. Cl. CPC H01L 23/315; H01L 21/762; H01L 21/76805; H01L 23/49816

(57) ABSTRACT

An electronic device is provided and includes a substrate having an active surface and a sensor disposed on an active surface of the substrate, where the sensor is in communication with the active surface of the substrate. The electronic device further includes a continuous wall having an open top disposed on the active surface of the substrate, where the continuous wall surrounds the sensor. A cover is disposed on a top surface of the continuous wall, where the cover closes off the open top of the continuous wall to form a cavity inside the continuous wall to prevent foreign substance from entering the cavity.

### TECHNICAL FIELD

The present disclosure relates to an electronic device and more specifically, to an integrated circuit package that includes a sensor disposed in a capped cavity.

### BACKGROUND

Cavity integrated circuit (IC) packages are used as sensor packages to measure various physical properties of an environment such as humidity, temperature, optics, sound, pressure, adverse environmental conditions, etc. Thus, the cavity packages include a sensor disposed in a cavity to sense the physical property and other circuitry to process the sensed physical property. In order for the sensor to function properly, the cavity must be free from any substance (e.g. solder, mold compound, external environmental environment, etc.). Any substance that enters the cavity during fabrication of the cavity package can compromise the operation of the sensor.

### SUMMARY

In described examples, an electronic device includes a substrate having an active surface and a sensor disposed on an active surface of the substrate, the sensor being in communication with the active surface of the substrate. The electronic device further includes a continuous wall having an open top disposed on the active surface of the substrate, the continuous wall surrounds the sensor. A cover is disposed on a top surface of the continuous wall, where the cover closes off the open top of the continuous wall to form a cavity inside the continuous wall to prevent foreign substance from entering the cavity.

In another described example, a method includes providing a substrate, where the substrate includes an active surface and placing a sensor on the active surface of the substrate. A continuous wall is deposited on the active surface of the substrate around the sensor. A cover is formed over the continuous wall to close off an open top of the continuous wall to thereby form a cavity inside the continuous wall.

### BRIEF DESCRIPTION OF THE DRAWINGS

FIG. 1A is a cross section view of an example electronic device.

FIG. 1B is a cross section view of an alternative example electronic device that includes a mold compound.

FIG. 2 is a block diagram illustration of a method of fabricating the electronic device of FIG. 1A.

FIG. 3A is a top view of a substrate array (wafer).

FIG. 3B illustrates a cross section view of a singulated substrate chip (hereinafter “substrate”) from the substrate array in FIG. 3A in the early stages of fabrication of an electronic device.

FIG. 3C illustrates a cross section view of the electronic device in FIG. 3B that includes a sensor disposed on an active surface of the substrate.

FIG. 3D illustrates a cross section view of the electronic device in FIG. 3C after the deposition of conductive metal pads on the active surface of the substrate.

FIG. 3E illustrates a cross section view of the electronic device of FIG. 3D after the formation of a first lamination film on the active surface of the substrate.

FIG. 3F illustrates a side view of the electronic device of FIG. 3E after undergoing a first photoresist material layer patterning.

FIG. 3G illustrates a side view of the electronic device of FIG. 3F after undergoing a first etch process and removal of the first photoresist material layer.

FIG. 3H illustrates a cross section view of the electronic device of FIG. 3G after undergoing a second photoresist material layer patterning.

FIG. 3I illustrates a cross-sectional view of the electronic device of FIG. 3H after undergoing a second etch process and removal of the second photoresist material layer.

FIG. 3J illustrates a cross-sectional view of the electronic device of FIG. 3I after undergoing a third photoresist material layer patterning.

FIG. 3K illustrates a cross section view of the electronic device of FIG. 3J after undergoing a plating process and removal of the third photoresist material layer.

FIG. 3L illustrates a cross section view of the electronic device of FIG. 3K after undergoing the formation of a second lamination film.

FIG. 3M illustrates a cross section view of the electronic device of FIG. 3L after removal of outer portions of the second lamination film.

FIG. 3N illustrates a cross section view of the electronic device of FIG. 3M after deposition of solder balls on under bump metallization layers.

### DETAILED DESCRIPTION

Cavity integrated circuit (IC) packages are used as sensor packages to measure various physical properties of an environment such as humidity, temperature, optics, sound, pressure, adverse environmental conditions, etc. Thus, the cavity packages include a sensor disposed in a cavity to sense the physical property and other circuitry to process the sensed physical property. In order for the sensor to function properly, the cavity must be free from any external elements or substance (e.g. solder, mold compound, external environmental elements, etc.).

Some IC packages include a cavity in the form of a ring comprised of a plated circular wall. In some cavity packages the cavity is open. In other words, the top of the cavity is open, referred to an open cavity package (OCP). Thus, the sensor inside the cavity is exposed to the external environment. The remaining package circuitry outside the cavity, however, is covered by a mold compound to protect the outside circuitry from the external environment.

In other cavity packages, the top of the cavity is covered or closed off, referred to as a closed (covered) cavity package (CCP). Current processes of creating and covering the cavity require several photolithography steps. First, a first lamination film is deposited on a substrate. The first lamination film is exposed and developed to form the walls of the cavity. Another lamination film is deposited on the first lamination film. The second lamination film is then exposed and developed to form the cover over the cavity. An additional photolithography step is required to deposit a metal plating in openings formed in the first and second lamination films to form conductive terminals of the IC package.

Another processes of covering the top of the cavity includes depositing solder across the top of the cavity. During a reflow process, however, solder flows down an inside surface of the cavity wall into the cavity area. In other processes, plated solder domes or solder paste domes fail to completely close off the top opening of the cavity thereby leaving openings in the cavity cover or dome. As a result, during formation of the molding compound, the molding compound can enter the cavity through the openings of the cover or dome thereby compromising the operation of the sensor.

Disclosed herein is an electronic device and more specifically, a cavity integrated circuit (IC) package and method of fabricating the package that overcomes the challenges described above. The electronic device includes a substrate that includes a sensor and trenches etched around the sensor to isolate the sensor from stresses that may occur during fabrication, installation, and/or use. The electronic device further includes a metal plated wall formed on an active surface of the substrate that surrounds the sensor. A cover comprising a lamination film is formed on the wall surrounding the sensor thereby forming a cavity that encloses the sensor. The electronic device further includes under bump metallization (UBM) layers formed on the active surface of the die. Solder is deposited on the UBM layers to form an electrical connection from the active surface of the substrate to an external electronic device (e.g., printed circuit board (PCB)).

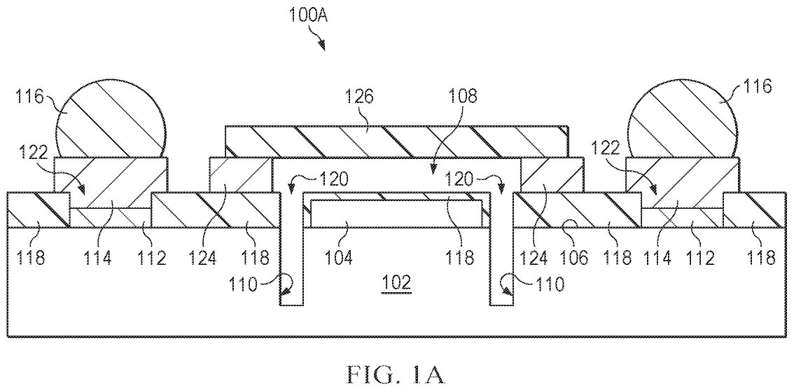

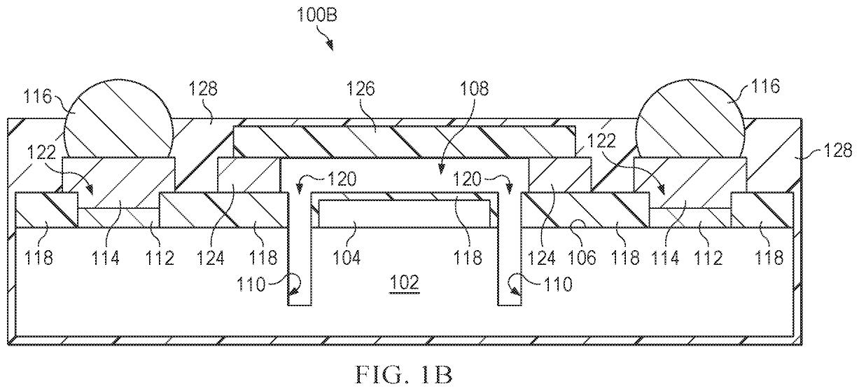

FIG. 1A is a cross-sectional view of an example electronic device 100A comprising a substrate (e.g., silicon wafer) 102, a sensor 104 formed in or on an active surface 106 of the substrate 102, and a cavity 108 that houses the sensor 104. The electronic device 100A can be comprised of an integrated circuit (IC) including, but not limited to a flip-chip package, a Ball-Grid Array (BGA) package, etc. Although the example electronic device 100A illustrated in FIG. 1A shows the substrate 102 having a single sensor 104 disposed in the cavity 108, in other examples the electronic device 100 can include multiple cavities having one or more sensors disposed in each cavity. Thus, the electronic device 100A illustrated in FIG. 1A is for illustrative purposes only and is not intended to limit the scope of the invention.

The substrate 102 includes a continuous trench 110 formed around the sensor 104 for the purpose of isolating the sensor 104 from stress during fabrication, installation, or use of the electronic device 100A. In one example, at a wafer level the sensor 104 is integrated into the active surface 106 of the substrate 102 such that a top surface of the sensor 104 is substantially flush with the active surface 106 of the substrate 102. In another example, the sensor 104 can be partially integrated into the active surface 106 of the substrate 102 such that the sensor 104 partially extends above the active surface 106 of the substrate 102. In still yet another example, the sensor 104 can be disposed on the active surface 106 of the substrate 102 such that the sensor 104 is fully above the substrate 102. The sensor 104 may be configured to sense any of a variety of physical properties, such as humidity, light, sound, pressure, bulk acoustic waves, surface acoustic waves, stress, temperature, current, voltage, power, motion, acceleration, magnetic fields, and other physical properties. The active surface 106 of the substrate may include other circuitry coupled to the sensor 104 that is configured to receive and process signals from the sensor 104 in an appropriate manner. For example, a probing element (not shown) that interrogates the sensor 104 to produce a signal can be disposed below the sensor 104 in the form of an interdigitated lateral comb pattern, across or partially around the sensor 104, or sandwiched above and below the sensor 104. The interrogating signal can be in the form of frequency, current, resistance, capacitance, etc.

Conductive pads 112 are disposed on the active surface 106 of the substrate 102. Interconnects (UBM layers) 114 are electroplated onto the conductive pads 112 and solder 116 is deposited on a top surface of the interconnects 114. The conductive pads 112, interconnects 114, and solder 116 form an electrical connection from the substrate 102 to an external electronic device (e.g., printed circuit board (PCB)).

A first lamination film 118 is formed on the active surface 106 of the substrate 102 and includes a continuous opening 120 that is aligned with the trench 110. In the example illustrated in FIG. 1A, the first lamination film 118 is formed over the sensor 104. In addition, the first lamination film 118 includes openings 122 formed over the conductive pads 112 to thereby expose the conductive pads 112 in order to receive the interconnects 114.

A continuous wall (e.g., plated metal wall) 124 is formed on the first lamination film 118 and surrounds the sensor 104. The continuous wall 124 has an open top and is formed via an electro-plating process as explained below and may have any shape (e.g., circular, square, rectangular, etc.). The continuous wall 124 may be formed from a metal such as but not limited to copper, aluminum, nickel, iron, etc. Dimensions of the continuous wall 124 are specific to the sensing application. For example, the continuous wall 124 may have a height ranging from 5 um to 500 um and a width (thickness) ranging from 5 um to 1000 um. The continuous wall 124 may have an inner diameter ranging from 10 um to 1000 um.

A cover (e.g., second lamination film) 126 is formed on a top of the continuous wall 124 and closes off the open top to thereby enclose the sensor 104 to protect the sensor from external elements or substances (e.g. solder, mold compound, external environmental elements, etc.). The cover 126 may have a thickness ranging from 5 um to 500 um. In an alternative example of an electronic device 100B illustrated in the cross-sectional view in FIG. 1B, as an option, a mold compound 128 can be formed over the substrate 102, the sensor 104, and the cavity 108 for added protection from external elements.

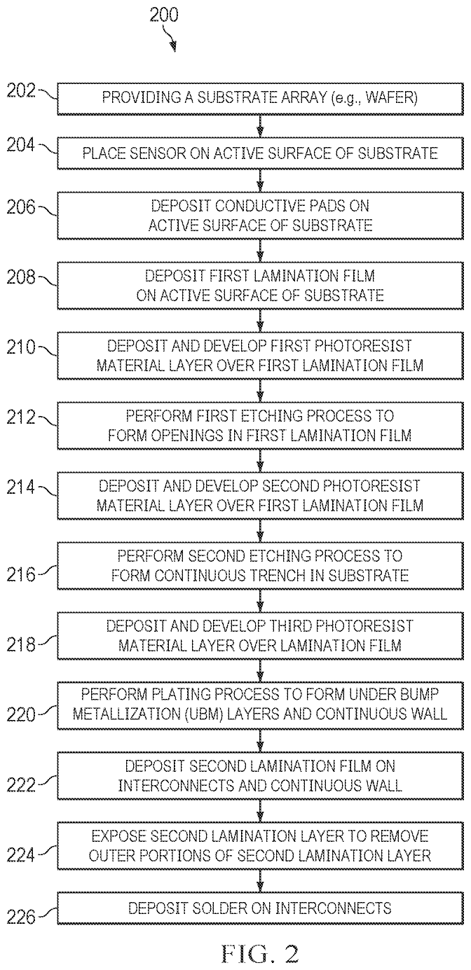

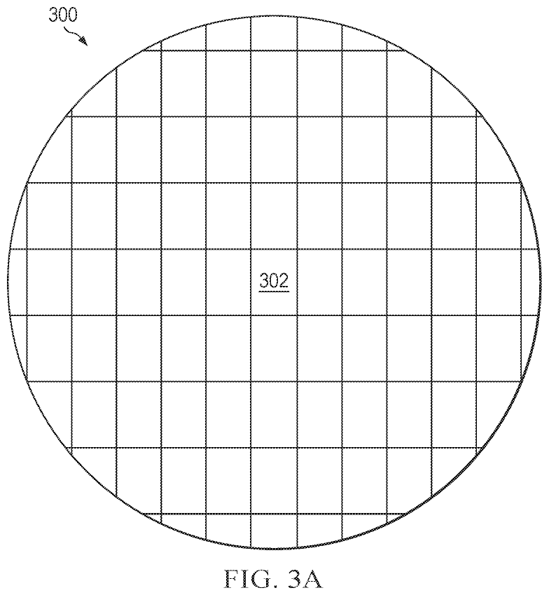

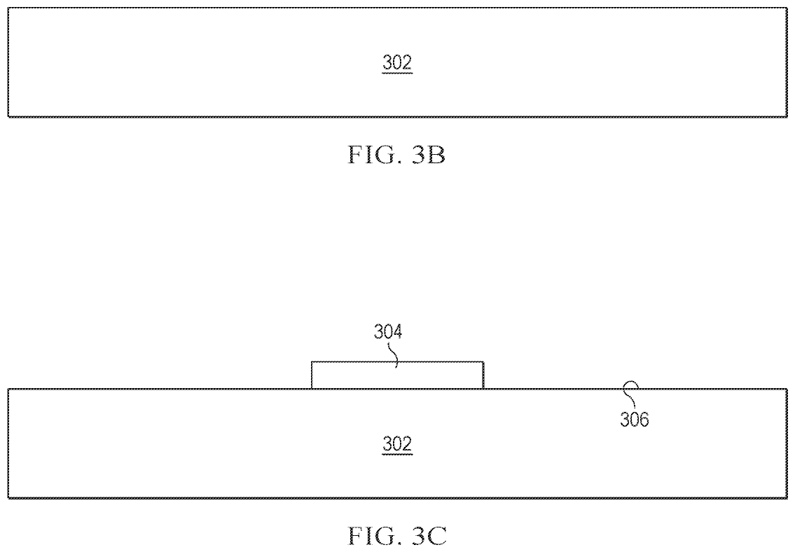

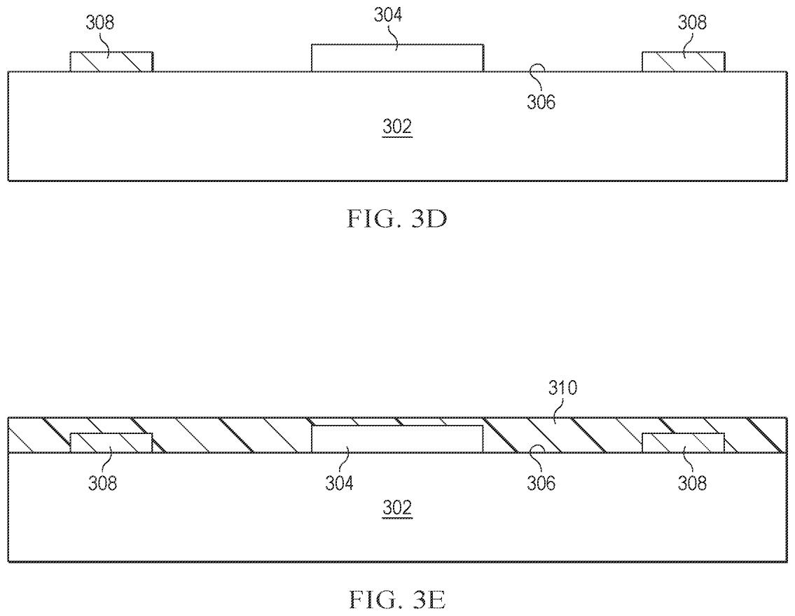

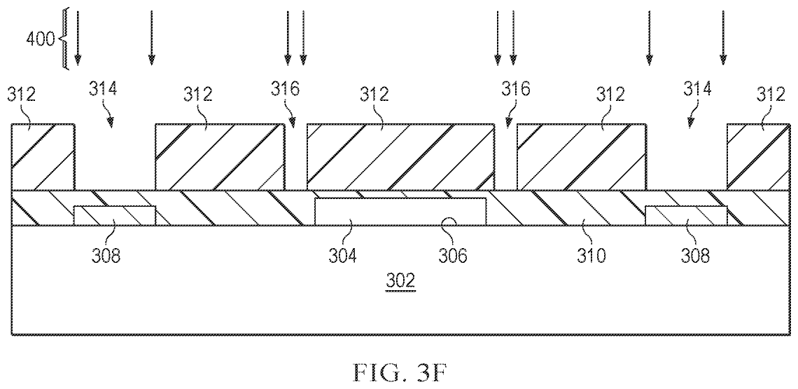

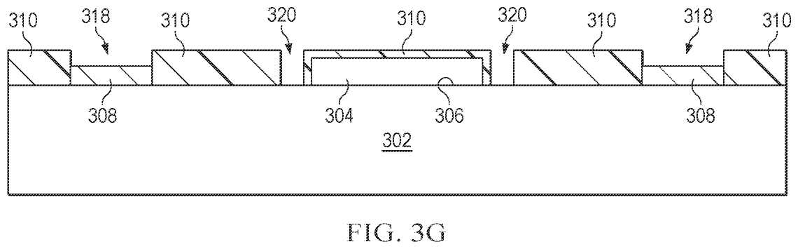

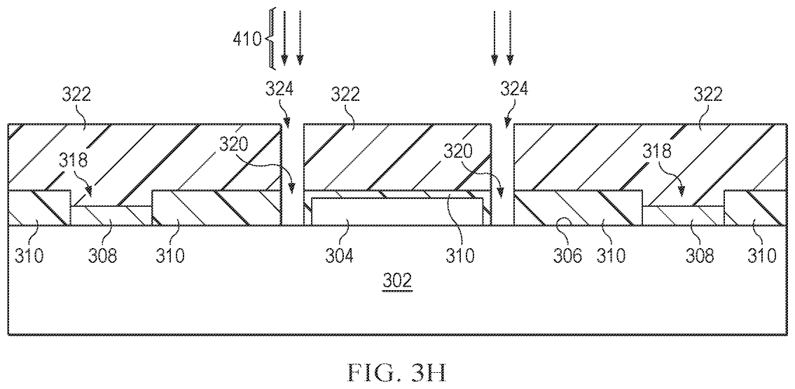

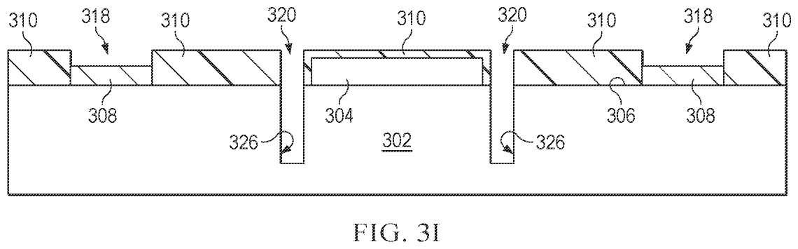

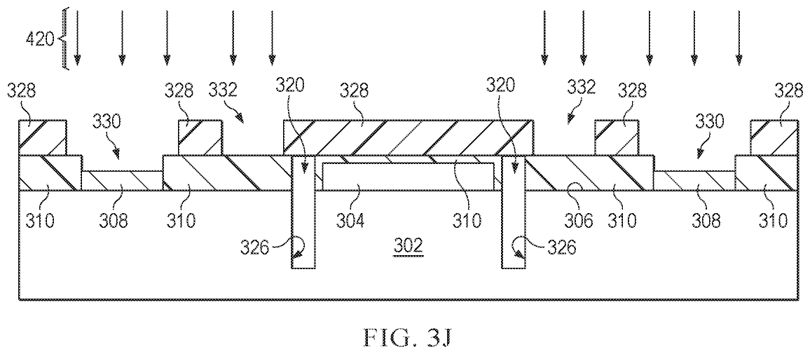

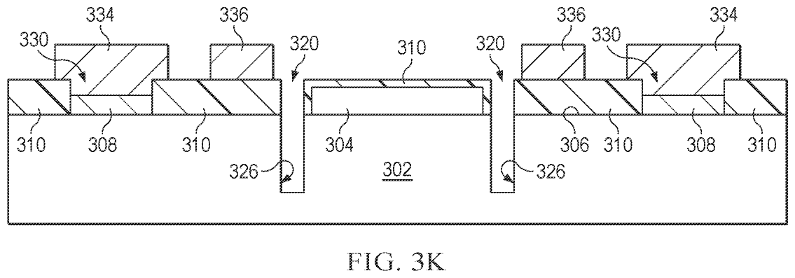

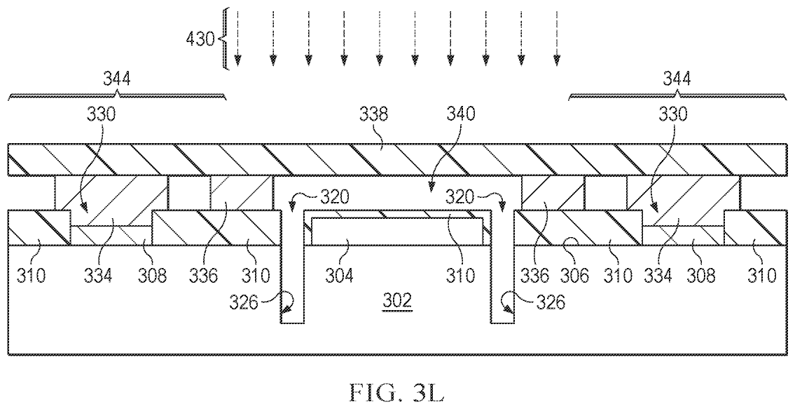

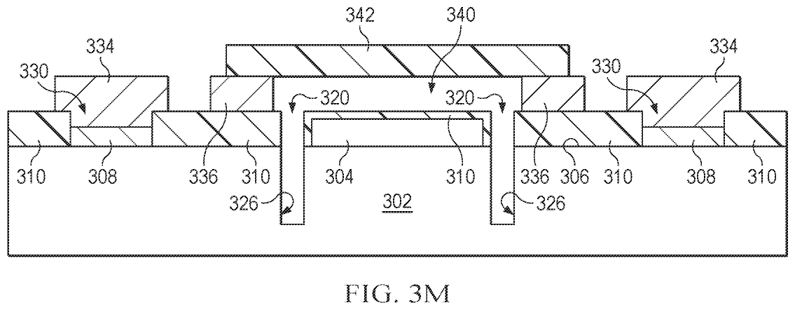

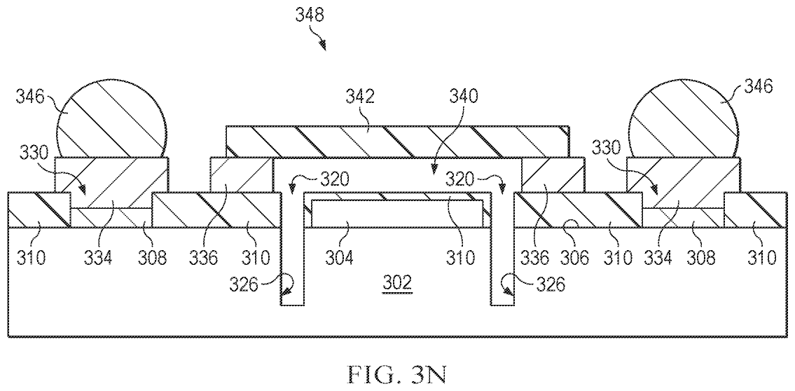

FIGS. 2 and 3A-3P illustrate a fabrication process associated with the fabrication of the electronic device 100A illustrated in FIG. 1A. Specifically, FIG. 2 is a block diagram explanation of the fabrication process steps 200 and FIGS. 3A-3P illustrate the fabrication process associated with the formation of the electronic device 100A illustrated in FIG. 1A. Though depicted sequentially as a matter of convenience, at least some of the actions shown can be performed in a different order and/or performed in parallel. Alternatively, some implementations may perform only some of the actions shown. Still further, although the example illustrated in FIGS. 2 and 3A-3P is an example method illustrating the example configuration of FIG. 1A, other methods and configurations are possible. It is understood that although the method illustrated in FIGS. 2 and 3A-3P depicts the fabrication process of a single electronic device, the process applies to an array electronic devices. Thus, after fabrication of the array of electronic devices the array is singulated to separate each electronic device 100A from the array.

Referring to FIGS. 2 and 3A-3P, the fabrication process for the electronic device 100A illustrated in FIG. 1A begins at 202 with a substrate array (e.g., wafer) 300, as illustrated in FIG. 3A. Specifically, FIG. 3A is a schematic diagram of a substrate array 300, in accordance with various examples. For example, the substrate array 300 may be a silicon wafer. The manufacturing techniques described below may be performed on individual substrate (wafer) chips 302 (post-singulation), or the techniques may be more efficiently performed on a mass scale, e.g., simultaneously on multiple substrate chips 302 of the substrate array 300 (pre-singulation). For convenience and clarity, the remaining drawings show a single substrate (wafer) chip 302, with the understanding that the processes described herein as being performed on the single substrate chip 302 may also be performed (e.g., sequentially performed, simultaneously performed) on the remaining substrate chips 302 of the substrate array 300.

FIG. 3B illustrates a cross section view of a single substrate chip (hereinafter “substrate”) 302 singulated from the substrate array 300. At 204, a sensor 304 is deposited on an active surface 306 of the substrate 302 resulting in the configuration of FIG. 3C. As explained above, in another example, the sensor 304 can be integrated into the active surface 306 of the substrate 302 such that a top surface of the sensor 304 is substantially flush with the active surface 306 of the substrate 302. In still another example, the sensor 304 can be partially integrated into the active surface 306 of the substrate 302. For example, in an application where the sensor 304 is configured to sense humidity, the sensor 304 is integrated into the substrate 302 as a lateral capacitor. The lateral capacitor uses a transducer medium (e.g., polyimide) on top as a functionalized material that will change a di-electric constant with varying levels of humidity resulting in a change of capacitance.

At 206, conductive pads 308 are deposited on the active surface 306 of the substrate 302 resulting in the configuration in FIG. 3D. The conductive pads 308 may be comprised of an electrically conductive metal (e.g., copper, aluminum, etc.). At 208, a first lamination film 310 is deposited on the active surface 306 of the substrate 302, such that the first lamination film 310 covers the sensor 304 and the conductive pads 308, resulting in the configuration of FIG. 3E. At 210, a first photoresist material layer 312 overlies the first lamination film 310 and is patterned and developed to expose openings 314 in the first photoresist material layer 312 over the conductive pads 308 and an opening 316 that surrounds the sensor 304, resulting in the configuration of FIG. 3F. The first photoresist material layer 312 can have a thickness that varies in correspondence with the wavelength of radiation used to pattern the first photoresist material layer 312. The first photoresist material layer 312 may be formed over the first lamination film 310 via spin-coating or spin casting deposition techniques, selectively irradiated (e.g., via deep ultraviolet (DUV) irradiation) and developed to form the openings 314.

At 212, the configuration in FIG. 3F undergoes a first etching process 400 to form openings 318 in the first lamination film 310 over the conductive pads 308 thereby exposing a surface of the conductive pads 308 and to also form a continuous opening 320 in the first lamination film 310 that surrounds the sensor 304. The first photoresist material layer 312 is then removed, resulting in the configuration of FIG. 3G. At 214, a second photoresist material layer 322 overlies the first lamination film 310 and is patterned and developed to expose a continuous opening 324 in the second photoresist material layer 322 that aligns with the continuous opening 320 in the first lamination film 310, resulting in the configuration of FIG. 3H. The second photoresist material layer 322 can have a thickness that varies in correspondence with the wavelength of radiation used to pattern the second photoresist material layer 322. The second photoresist material layer 322 may be formed over the first lamination film 310 via spin-coating or spin casting deposition techniques, selectively irradiated (e.g., via deep ultraviolet (DUV) irradiation) and developed to form the openings 324.

At 216, the configuration in FIG. 3H undergoes a second etching process 410 to form a continuous trench 326 in the substrate 302 that surrounds the sensor 304. The second photoresist material layer 322 is then removed, resulting in the configuration of FIG. 3I. At 218, a third photoresist material layer 328 overlies the first lamination film 310 and is patterned and developed to expose openings 330 in the third photoresist material layer 328 over the conductive pads 308 and openings 332 between the continuous trench 326 and the conductive pads 308, resulting in the configuration of FIG. 3J. The third photoresist material layer 328 can have a thickness that varies in correspondence with the wavelength of radiation used to pattern the third photoresist material layer 328. The third photoresist material layer 328 may be formed over the first lamination film 310 via spin-coating or spin casting deposition techniques, selectively irradiated (e.g., via deep ultraviolet (DUV) irradiation) and developed to form the openings 330, 332.

At 220, the configuration in FIG. 3J undergoes a plating process 420 to form interconnects (e.g., UBM layers) 334 on the conductive pads 308 and to form a continuous wall 336 on the first lamination film 310 that surrounds the sensor 304 and the continuous trench 326. The third photoresist material layer 328 is then removed, resulting in the configuration of FIG. 3K. At 222, a second lamination film 338 is deposited on the interconnects 334 and the continuous wall 336 thereby forming a cavity 340 covering the sensor 304, resulting in the configuration of FIG. 3L. At 224, a portion of the second lamination film 338 that forms a cover 342 over the cavity 340 is exposed to ultra-violet (UV) light 430 to thereby allowing outer portions 344 of the second lamination film 338 to be removed via a liquidous solution, resulting in the configuration of FIG. 3M. Specifically, the second lamination film 338 is a negative photoresist material layer that when exposed to UV light become cross- linked. Thus, any portion of the second lamination film 338 that is not exposed to UV light can be washed away by a liquidous solution. Thus, only the portion of the second lamination film 338 that forms the cover 342 is exposed to the UV light 430 and the outer portions 344 are removed via the liquidous solution. At 226, solder 346 is placed on the interconnects 334, resulting in the electronic device 348 illustrated in the configuration of FIG. 3N.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. An electronic device comprising:
a substrate having an active surface;
a sensor disposed on the active surface of the substrate, the sensor being in communication with the active surface of the substrate;
a continuous wall disposed on the active surface of the substrate, the continuous wall surrounding the sensor, the continuous wall having an open top; and
a cover disposed on a top surface of the continuous wall, the cover closing off the open top of the continuous wall to form a cavity inside the continuous wall to prevent foreign substance from entering the cavity.

2. The electronic device of claim 1, wherein the substrate includes a continuous trench defined therein that surrounds the sensor to isolate the sensor from stress that may occur during fabrication, installation, and/or use.

3. The electronic device of claim 2 further comprising conductive pads disposed on the active surface of the substrate.

4. The electronic device of claim 3 further comprising a first lamination film formed on the active surface of the substrate, the first lamination film being formed over the sensor.

5. The electronic device of claim 4, wherein the first lamination film includes a continuous opening that aligns with the continuous trench and openings aligned with the conductive pads to thereby expose the conductive pads.

6. The electronic device of claim 4, wherein the continuous wall is formed on the first lamination film.

7. The electronic device of claim 4, wherein the cover is comprised of a second lamination film.

8. The electronic device of claim 3 further comprising interconnects formed on the conductive pads, the conductive pads and the interconnects providing an electrical connection via solder from the substrate to an external electronic device.

9. The electronic device of claim 8, wherein the interconnects are under bump metallization layers.

10. The electronic device of claim 1 further comprising a mold compound formed over the substrate, the sensor, and the cavity.

11. The electronic device of claim 1, wherein the continuous wall has a circular, square, or rectangular shape.

12. A method comprising:
providing a substrate, the substrate having an active surface;
placing a sensor on the active surface of the substrate;
depositing a continuous wall on the active surface of the substrate around the sensor; and
forming a cover over the continuous wall to close off an open top of the continuous wall to thereby form a cavity inside the continuous wall.

13. The method of claim 12, wherein providing the substrate includes etching a continuous trench in the substrate, the continuous trench surrounding the sensor.

14. The method of claim 13, wherein providing the substrate further includes depositing conductive pads on the active surface of the substrate.

15. The method of claim 14, wherein prior to depositing the continuous wall on the active surface of the substrate, the method comprising depositing a first lamination film on the active surface of the substrate, the first lamination film being formed over the sensor.

16. The method of claim 15 further comprising etching a continuous opening in the first lamination film, the continuous opening being aligned with the continuous trench in the substrate.

17. The method of claim 16 further comprising etching openings in the first lamination film, the openings being aligned with the conductive pads to thereby expose the conductive pads.

18. The method of claim 14, wherein depositing the continuous wall on the active surface of the substrate includes performing an electroplating process to deposit metal on the active surface of the substrate to form the continuous wall.

19. The method of claim 18 further comprising performing the electroplating process to form interconnects on the conductive pads.

20. The method of claim 19, wherein the continuous wall is formed in a circular, square, or rectangular shape.
